(19) United States
(12) Patent Application Publication
(10) Pub. No.: US 2026/0350267 A1
(43) Pub. Date: Nov. 5, 2026

(54) SYSTEM AND METHOD FOR SEMI-AUTOMATED PRODUCT DESIGN FEEDBACK LOOP WITH VIRTUAL AGENTS

(71) Applicant: TOYOTA RESEARCH INSTITUTE, INC., Los Altos, CA (US)

(72) Inventors: Matthew K. HONG, Mountain View, CA (US); Yin-Ying CHEN, San Jose, CA (US); Matthew Evans KLENK, San Francisco, CA (US)

(73) Assignees: TOYOTA RESEARCH INSTITUTE, INC., Los Altos, CA (US); TOYOTA JIDOSHA KABUSHIKI KAISHA, Aichi-Ken (JP)

(21) Appl. No.: 19/196,535

(22) Filed: May 1, 2025

(51) Int. Cl. G06F 30/27

(52) U.S. Cl. CPC G06F 30/27

(57) ABSTRACT

A method for a semi-automated product design is described. The method includes training a first virtual population in a first machine learning (ML) model that represents a first demographic. The method also includes training a second virtual population in a second ML model that represents a second defined demographic. The method further includes iteratively generating variations of a first demographic design based on first feedback votes received from the first ML model as selections between competing, first demographic designs, starting from an initial design. The method also includes iteratively generating variations of a second demographic design based on second feedback votes received from the second ML model as a selection between competing, second demographic designs, starting from the initial design.

### BACKGROUND

### Field

Certain aspects of the present disclosure generally relate to machine assisted design and, more particularly, to a system and method for semi-automated product design feedback loop with virtual agents.

### Background

For product design, designers often generate many different concept sketches during ideation. These sketches generally include many different views of the product (e.g., vehicle). Thus, the same group of designers working on a single design may generate many sketches that are distinct while working toward a final design goal. Based on these early sketches, different designers/managers may provide feedback. In particular, designers present their work, explaining the goals and rationale behind their decisions. Team members provide feedback, emphasizing diverse perspectives to refine ideas and address potential issues. The group evaluates designs against key design guidelines, brand identity, project goals, and user needs to ensure decisions are grounded in both creativity and practicality.

This product design involves a complex decision-making process to incorporate the various feedback to provide a final product design. The feedback may include highlighting different aspects of different designs. For example, this feedback may combine different designs, such as a bumper from one vehicle, a quarter panel design of another, a roof line of a third, etc. Unfortunately, collecting feedback on distinct aspects of different parts in parallel, from diverse populations, and simultaneously, is challenging and, generating designs or adaptations of designs that are specific to different demographic groups, can also be difficult. A framework for ideation across different demographic groups, is desired.

### SUMMARY

A method for a semi-automated product design is described. The method includes training a first virtual population in a first machine learning (ML) model that represents a first demographic. The method also includes training a second virtual population in a second ML model that represents a second defined demographic. The method further includes iteratively generating variations of a first demographic design based on first feedback votes received from the first ML model as selections between competing, first demographic designs, starting from an initial design. The method also includes iteratively generating variations of a second demographic design based on second feedback votes received from the second ML model as a selection between competing, second demographic designs, starting from the initial design.

A non-transitory computer-readable medium having program code recorded thereon for a semi-automated product design is described. The program code is executed by a processor. The non-transitory computer-readable medium includes program code to train a first virtual population in a first machine learning (ML) model that represents a first demographic. The non-transitory computer-readable medium also includes program code to train a second virtual population in a second ML model that represents a second defined demographic. The non-transitory computer-readable medium further includes program code to iteratively generate variations of a first demographic design based on first feedback votes received from the first ML model as selections between competing, first demographic designs, starting from an initial design. The non-transitory computer-readable medium also includes program code to iteratively generate variations of a second demographic design based on second feedback votes received from the second ML model as a selection between competing, second demographic designs, starting from the initial design.

A system for a semi-automated product design is described. The system includes a first virtual population model trained according to a first virtual population using a first machine learning (ML) model that represents a first demographic. The system also includes a first virtual population model to trained according to a second virtual population in using a second ML model that represents a second defined demographic. The system further includes an iterative first demographic design module to iteratively generate variations of a first demographic design based on first feedback votes received from the first ML model as selections between competing, first demographic designs, starting from an initial design. The system also includes an iterative first demographic design module to iteratively generate variations of a second demographic design based on second feedback votes received from the second ML model as a selection between competing, second demographic designs, starting from the initial design.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of designing a neural network using a system-on-a-chip (SOC) of a semi-automated product design feedback loop system with virtual agents, in accordance with aspects of the present disclosure.

FIG. 2 is a block diagram illustrating an exemplary software architecture that may modularize artificial intelligence (AI) functions for a semi-automated product design feedback loop system with virtual agents, according to aspects of the present disclosure.

FIG. 3 is a diagram illustrating a hardware implementation for a semi-automated product design feedback loop system using virtual agents, according to aspects of the present disclosure.

FIG. 4 is a block diagram illustrating a semi-automated product design feedback loop system, according to various aspects of the present disclosure.

FIG. 5 is a block diagram illustrating an iterative feedback loop simulation for product design involving different populations, according to various aspects of the present disclosure.

FIG. 6 is a process flow diagram illustrating a method for a semi-automated product design, according to various aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

Based on the teachings, one skilled in the art should appreciate that the scope of the present disclosure is intended to cover any aspect of the present disclosure, whether implemented independently of or combined with any other aspect of the present disclosure. For example, an apparatus may be implemented, or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure disclosed may be embodied by one or more elements of a claim.

Although particular aspects are described herein, many variations and permutations of these aspects fall within the scope of the present disclosure. Although some benefits and advantages of the preferred aspects are mentioned, the scope of the present disclosure is not intended to be limited to particular benefits, uses, or objectives. Rather, aspects of the present disclosure are intended to be universally applicable to different technologies, system configurations, networks, and protocols, some of which are illustrated by way of example in the figures and in the following description of the preferred aspects. The detailed description and drawings are merely illustrative of the present disclosure, rather than limiting the scope of the present disclosure being defined by the appended claims and equivalents thereof.

For product design, designers often generate many different concept sketches during ideation. These sketches generally include many different views of the product (e.g., vehicle). Thus, the same group of designers working on a single design may generate many sketches that are distinct while working toward a final design goal. Based on these early sketches, different designers/managers may provide feedback. In particular, designers present their work, explaining the goals and rationale behind their decisions. Team members provide feedback, emphasizing diverse perspectives to refine ideas and address potential issues. The group evaluates designs against key design guidelines, brand identity, project goals, and user needs to ensure decisions are grounded in both creativity and practicality.

This product design involves a complex decision-making process to incorporate the various feedback to provide a final product design. The feedback may include highlighting different aspects of different designs. For example, this feedback may combine different designs, such as a bumper from one vehicle, a quarter panel design of another, a roof line of a third, etc. The result of this process and feedback may be that a combined design is generated via a vision-based machine learning model that supports multi-view to novel-view synthesis. Unfortunately, collecting feedback on distinct aspects of different parts in parallel, from diverse populations, and simultaneously, is challenging and, generating designs or adaptations of designs that are specific to different demographic groups, can also be difficult. A framework for ideation across different demographic groups, is desired.

Various aspects of the present disclosure are directed to a semi-automatic product design feedback loop using virtual design agents. In some implementations, a semi-automatic product design feedback loop system assists designers with customizing their design choices for specific populations through feedback collection and automated fine-tuning using a multimodal generative model. In particular, the semi-automatic product design feedback loop system helps designers tailor their design choices to specific populations utilizting the fine-grained design process. A semi-automatic product design feedback loop process involves collecting feedback from target populations through surveys and using that feedback to fine-tune a generative model. The generative model may be multimodal, incorporating text, images, and potentially voice, and can automate the iterative fine-tuning loop.

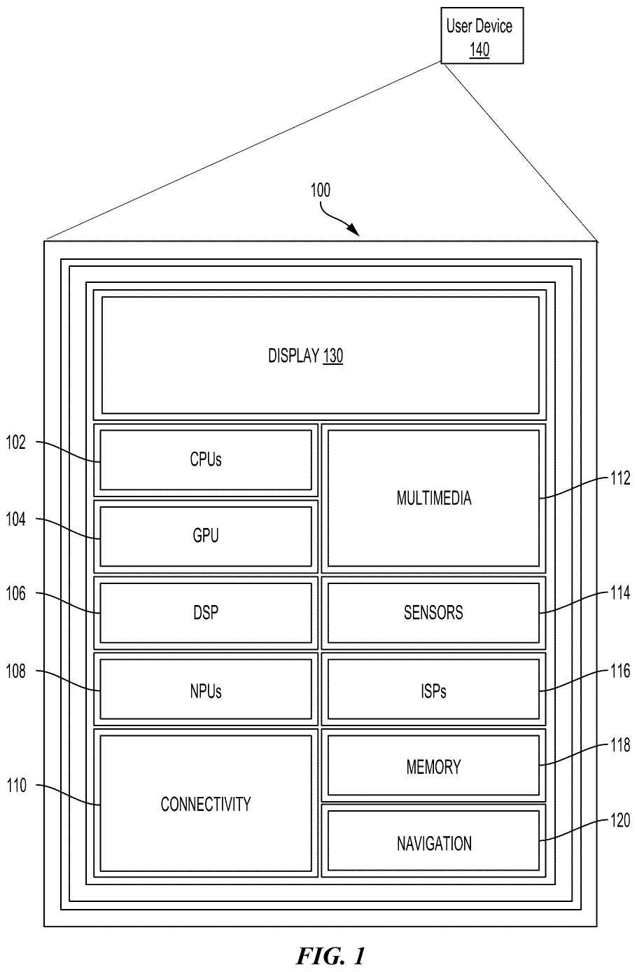

FIG. 1 illustrates an example implementation of the aforementioned system and method for a semi-automated product design feedback loop system with virtual agents using a system-on-a-chip (SOC) 100, according to aspects of the present disclosure. The SOC 100 may include a single processor or multi-core processors (e.g., a central processing unit (CPU) 102), in accordance with certain aspects of the present disclosure. Variables (e.g., neural signals and synaptic weights), system parameters associated with a computational device (e.g., neural network with weights), delays, frequency bin information, and task information may be stored in a memory block. The memory block may be associated with a neural processing unit (NPU) 108, a CPU 102, a graphics processing unit (GPU) 104, a digital signal processor (DSP) 106, a dedicated memory block 118, or may be distributed across multiple blocks. Instructions executed at a processor (e.g., CPU 102) may be loaded from a program memory associated with the CPU 102 or may be loaded from the dedicated memory block 118.

The SOC 100 may also include additional processing blocks configured to perform specific functions, such as the GPU 104, the DSP 106, and a connectivity block 110, which may include fourth generation long term evolution (4G LTE) connectivity, unlicensed Wi-Fi connectivity, USB connectivity, Bluetooth® connectivity, and the like. In addition, a multimedia processor 112 in combination with a display 130 may, for example, select a control action, according to the display 130 illustrating a view of a user device.

In some aspects, the NPU 108 may be implemented in the CPU 102, DSP 106, and/or GPU 104. The SOC 100 may further include a sensor processor 114, image signal processors (ISPs) 116, and/or navigation 120, which may, for instance, include a global positioning system. The SOC 100 may be based on an Advanced Risc Machine (ARM) instruction set, RISC-V, or any reduced instruction set computing (RISC) architecture, or the like. In another aspect of the present disclosure, the SOC 100 may be a server computer in communication with a user device 140. In this arrangement, the user device 140 may include a processor and other features of the SOC 100. In this aspect of the present disclosure, instructions loaded into a processor (e.g., the CPU 102) or the NPU 108 may include code to provide a semi-automated product design feedback loop system with virtual agents.

According to various aspects of the present disclosure, the instructions loaded into a processor (e.g., the NPU 108) may also include code to train a first virtual population in a first machine learning (ML) model that represents a first demographic. The instructions loaded into the processor (e.g., the NPU 108) may also include code to train a second virtual population in a second ML model that represents a second defined demographic. The instructions loaded into the processor (e.g., the NPU 108) may also include code to iteratively generate variations of a first demographic design based on first feedback votes received from the first ML model as selections between competing first demographic designs, starting from an initial design. The instructions loaded into the processor (e.g., the NPU 108) may also include code to iteratively generate variations of a second demographic design based on second feedback votes received from the second ML model as a selection between competing second demographic designs, starting from the initial design.

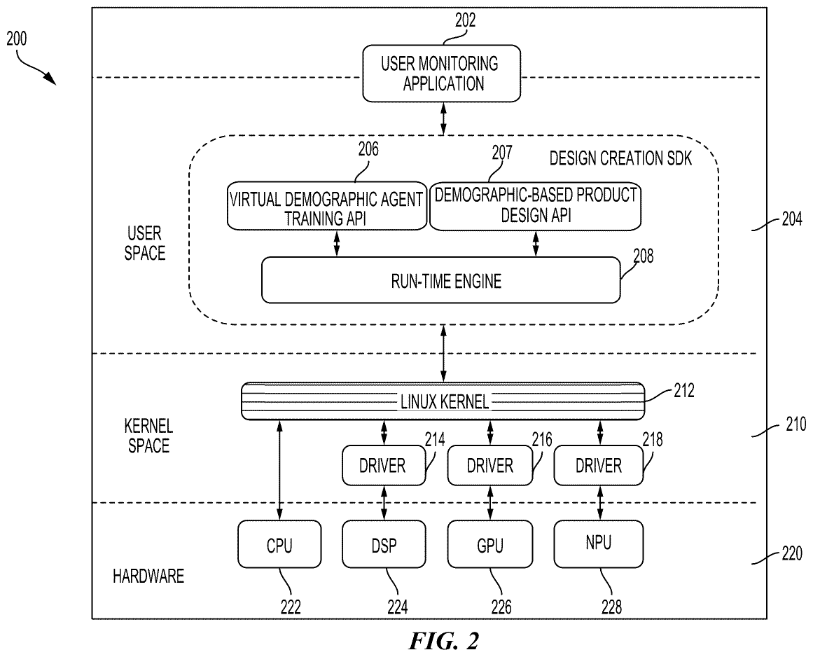

FIG. 2 is a block diagram illustrating a software architecture 200 that may modularize artificial intelligence (AI) functions for a semi-automated product design feedback loop system with virtual agents, according to aspects of the present disclosure. Using the architecture, a user monitoring application 202 may be designed such that it may cause various processing blocks of a system-on-a-chip (SOC) 220 (for example a CPU 222, a DSP 224, a GPU 226, and/or an NPU 228) to perform supporting computations during run-time operation of the user monitoring application 202. FIG. 2 describes the software architecture 200 for a semi-automated product design feedback loop system with virtual agents. It should be recognized that the semi-automated product design feedback loop system is not limited to any specific information. According to aspects of the present disclosure, the semi-automated product design functionality is applicable to any type of information selection activity.

The user monitoring application 202 may be configured to call functions defined in a user space 204 that may, for example, provide semi-automated product design services. The user monitoring application 202 may make a request for compiled program code associated with a library defined in a virtual demographic agent training application programming interface (API) 206. The virtual demographic agent training API 206 is configured to train a first virtual population in a first machine learning (ML) model that represents a first demographic. The virtual demographic agent training API 206 is further configured to train a second virtual population in a second ML model that represents a second defined demographic.

In some implementations following virtual demographic agent training, a demographic-based product design API 207 is configured to iteratively generate variations of a first demographic design based on first feedback votes received from the first ML model as selections between competing first demographic designs, starting from an initial design. Additionally, the demographic-based product design API 207 is configured to iteratively generate variations of a second demographic design based on second feedback votes received from the second ML model as a selection between competing second demographic designs, starting from the initial design.

A run-time engine 208, which may be compiled code of a run-time framework, may be further accessible to the user monitoring application 202. The user monitoring application 202 may cause the run-time engine 208, for example, to take actions for refining the virtual demographic agents to improve the demographic-based product designs. In response to a recommendation of visual content, the run-time engine 208 may in turn send a signal to an operating system 210, such as a Linux Kernel 212, running on the SOC 220. FIG. 2 illustrates the Linux Kernel 212 as software architecture for a semi-automated product design system. It should be recognized, however, that aspects of the present disclosure are not limited to this exemplary software architecture. For example, other kernels may provide the software architecture to support the semi-automated product design functionality.

The operating system 210, in turn, may cause a computation to be performed on the CPU 222, the DSP 224, the GPU 226, the NPU 228, or some combination thereof. The CPU 222 may be accessed directly by the operating system 210, and other processing blocks may be accessed through a driver, such as drivers 214, 216, 218 for the DSP 224, for the GPU 226, or for the NPU 228. In the illustrated example, the deep neural network may be configured to run on a combination of processing blocks, such as the CPU 222 and the GPU 226, or may be run on the NPU 228 if present.

As noted, products often generate many different concept sketches during ideation. These sketches generally include many different views of the product (e.g., vehicle). Thus, the same group of designers working on a single design may generate many sketches that are distinct while working toward a final design goal. Based on these early sketches, different designers/managers may provide feedback. In particular, designers present their work, explaining the goals and rationale behind their decisions. Team members provide feedback, emphasizing diverse perspectives to refine ideas and address potential issues. The group evaluates designs against key design guidelines, brand identity, project goals, and user needs to ensure decisions are grounded in both creativity and practicality.

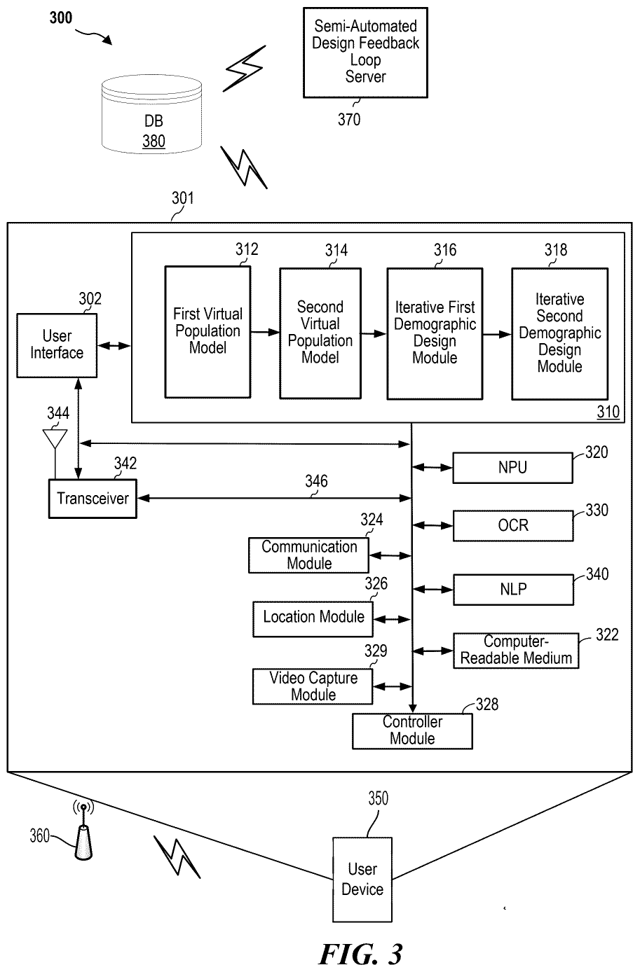

This product design involves a complex decision-making process to incorporate the various feedback to provide a final product design. The feedback may include highlighting different aspects of different designs. For example, this feedback may combine different designs, such as a bumper from one vehicle, a quarter panel design of another, a roof line of a third, etc. The result of this process and feedback may be that a combined design is generated via a vision-based machine learning model that supports multi-view to novel-view synthesis. Unfortunately, collecting feedback on distinct aspects of different parts in parallel, from diverse populations, and simultaneously, is challenging and, generating designs or adaptations of designs that are specific to different demographic groups, can also be difficult. A framework for ideation across different demographic groups, for example, is shown in FIG. 3.

FIG. 3 is a diagram illustrating a hardware implementation for a semi-automated product design feedback loop system 300 using virtual agents, according to aspects of the present disclosure. The semi-automated product design feedback loop system 300 may be configured to assist designers with customizing their design choices for specific populations through feedback collection and automated fine-tuning using a multimodal generative model. In particular, the semi-automated product design feedback loop system 300 helps designers tailor their design choices to specific populations without involving themselves in the fine-grained design process. For example, the semi-automated product design feedback loop system 300 is configured to collect feedback from target populations through surveys and use that feedback to fine-tune a generative model. The generative model may be multimodal, incorporating text, images, and potentially voice, and can automate an iterative fine-tuning loop for providing an output showing evolution of a design across iterations and populations.

The semi-automated product design feedback loop system 300 includes a user monitoring system 301 and a semi-automated design feedback loop server 370 in this aspect of the present disclosure. The user monitoring system 301 may be a component of a user device 350. The user device 350 may be a cellular phone (e.g., a smart phone), a personal digital assistant (PDA), a wireless modem, a wireless communications device, a handheld device, a laptop computer, a cordless phone, a wireless local loop (WLL) station, a tablet, a camera, a gaming device, a netbook, a Smartbook, an Ultrabook, a medical device or equipment, biometric sensors/devices, wearable devices (smart watches, smart clothing, smart glasses, smart wrist bands, smart jewelry (e.g., smart ring, smart bracelet)), an entertainment device (e.g., a music or video device, or a satellite radio), a global positioning system device, or any other suitable device that is configured to communicate via a wireless or wired medium.

The semi-automated design feedback loop server 370 may connect to the user device 350 once a first virtual population model and a second virtual population model are trained. For example, the semi-automated design feedback loop server 370 is configure for iteratively generating variations of a product design and have the virtual populations (e.g., the first virtual population model and the second virtual population model) vote on which is preferred until a predetermined condition is met. In some implementations, rank ordering and/or selection of preferred design variants are received feedback from a user of the first/second demographic are feedback to the semi-automated design feedback loop server 370. The condition may be a defined goal, such as more dynamic, more aggressive, etc. The semi-automated design feedback loop server 370 can then iterate designs while acquiring feedback from the virtual populations (e.g., the first virtual population model and the second virtual population model). The virtual populations can provide a simple vote or can include impressions of the iteration that is similar to the defined goal. The semi-automated design feedback loop server 370 can perform these iterations on parallel designs with separate virtual populations, which provide separate population-based options that can then be reconciled or used as the basis of independent designs.

The user monitoring system 301 may be implemented with an interconnected architecture, represented by an interconnect 346, which may be implemented as a controller area network (CAN). The interconnect 346 may include any number of point-to-point interconnects, buses, and/or bridges depending on the specific application of the user monitoring system 301 and the overall design constraints. The interconnect 346 links together various circuits including one or more processors and/or hardware modules, represented by a user interface 302, a user activity module 310, a neural network processor (NPU) 320, a computer-readable medium 322, a communication module 324, a location module 326, a video capture module 329, a controller module 328, an optical character recognition (OCR) 330, and a natural language processor (NLP) 340. The interconnect 346 may also link various other circuits such as timing sources, peripherals, voltage regulators, and power management circuits, which are well known in the art, and therefore, will not be described any further.

The user monitoring system 301 includes a transceiver 342 coupled to the user interface 302, the user activity module 310, the NPU 320, the computer-readable medium 322, the communication module 324, the location module 326, the video capture module 329, the controller module 328, the OCR 330, and NLP 340. The transceiver 342 is coupled to an antenna 344. The transceiver 342 communicates with various other devices over a transmission medium. For example, the transceiver 342 may receive commands via transmissions from a user. In this example, the transceiver 342 may receive/transmit information for the user activity module 310 to/from connected devices within the vicinity of the user device 350.

The user monitoring system 301 includes the NPU 320, the OCR 330, and the NLP 340 coupled to the computer-readable medium 322. The NPU 320, the OCR 330, and NLP 340 performs processing, including the execution of software stored on the computer-readable medium 322 to provide a neural network model for prior design/concept classification functionality to enable design intervention, according to the present disclosure. The software, when executed by the NPU 320, the OCR 330 and the NLP 340, causes the user monitoring system 301 to perform the various functions described for semi-automated product design as well as alternative designs presented to the user through the user device 350, or any of the modules (e.g., 310, 324, 326, 328, and/or 329). The computer-readable medium 322 may also be used for storing data that is manipulated by the OCR 330 and the NLP 340 when executing the software to analyze user communications.

The location module 326 may determine a location of the user device 350. For example, the location module 326 may use a global positioning system (GPS) to determine the location of the user device 350. The location module 326 may implement a dedicated short-range communication (DSRC)-compliant GPS unit. A DSRC-compliant GPS unit includes hardware and software to make the user device 350 and/or the location module 326 compliant with the following DSRC standards, including any derivative or fork thereof: EN 12253:2004 Dedicated Short-Range Communication—Physical layer using microwave at 5.8 GHz (review); EN 12795:2002 Dedicated Short-Range Communication (DSRC)—DSRC Data link layer: Medium Access and Logical Link Control (review); EN 12834:2002 Dedicated Short-Range Communication—Application layer (review); EN 13372:2004 Dedicated Short-Range Communication (DSRC)—DSRC profiles for RTTT applications (review); and EN ISO 14906:2004 Electronic Fee Collection—Application interface.

The communication module 324 may facilitate communications via the transceiver 342. For example, the communication module 324 may be configured to provide communication capabilities via different wireless protocols, such as 5G new radio (NR), Wi-Fi, long term evolution (LTE), 4G, 3G, etc. The communication module 324 may also communicate with other components of the user device 350 that are not modules of the user monitoring system 301. The transceiver 342 may be a communications channel through a network access point 360. The communications channel may include DSRC, LTE, LTE-D2D, mmWave, Wi-Fi (infrastructure mode), Wi-Fi (ad-hoc mode), visible light communication, TV white space communication, satellite communication, full-duplex wireless communications, or any other wireless communications protocol such as those mentioned herein.

The user monitoring system 301 also includes the OCR 330 and the NLP 340 to automatically detect multiple objects in an image displayed on the user's workspace as well as during presentations using the video capture module 329. The user monitoring system 301 may follow a process to detect and determine whether the user accesses creative content. When the user curates images, the user monitoring system 301 utilizes the OCR 330 and/or the NLP 340 to analyze designs of detected objects in the image displayed on the user's workspace.

The user activity module 310 may be in communication with the user interface 302, the NPU 320, the computer-readable medium 322, the communication module 324, the location module 326, the video capture module 329, the controller module 328, the OCR 330, the NLP 340, and the transceiver 342. In one configuration, the user activity module 310 monitors communications from the user interface 302. The user interface 302 may monitor user communications to and from the communication module 324. According to aspects of the present disclosure, the OCR 330 and the NLP 340 automatically detect images displayed on the user's workspace as well during presentations using the video capture module 329. In these aspects of the present disclosure, the OCR 330 and the NLP 340 use computer vision object detection and instance segmentation techniques to automatically detect the objects in the image to enable design action pattern analysis to enable determination product designs as well as variations of the designs for based on an input from virtual agents representing different demographics.

As shown in FIG. 3, the user activity module 310 includes a first virtual population model 312, a second virtual population model 314, an iterative first demographic design module 316, and an iterative second demographic design module 318. The first virtual population model 312 and the second virtual population model 314 may be components of a same or different artificial neural network, such as a large language model (LLM). Additionally, the iterative first demographic design module 316 and the iterative second demographic design module 318 may be components of a same or different artificial neural network, such as a multimodal generative model. The user activity module 310 is not limited to the noted LLM or multimodal generative model. The user activity module 310 monitors and analyzes design variations displayed on a user's workspace from the user interface 302 in response to virtual agent feedback.

This configuration of the user activity module 310 includes the first virtual population model 312 trained according to a first virtual population that represents a first demographic vote between competing product designs. Additionally, the second virtual population model 314 is trained according to a second virtual population that represents a second demographic vote between competing product designs, such that these models operate as virtual agents to provide feedback for guiding a product design.

According to various aspects of the present disclosure, the semi-automated product design feedback loop system 300 trains a virtual population within a large language model (LLM) that represents a defined demographic (e.g., Japanese, American, etc.) in the first virtual population model 312 and the second virtual population model 314. This includes defining preferences, styles, customs, and other aspects specific to the demographic relative to a product. A possible training process involves showing variations of a product and have individuals from the demographic vote on which is preferred. The variations may be generated using a text-to-image model. This provides training data that can be used to fine-tune the first virtual population model 312 and the second virtual population model 314 for the different populations.

The iterative first demographic design module 316 is configured to iteratively generate variations of a first demographic design based on first feedback votes received from the first virtual population model 312 as selections between competing first demographic designs, starting from an initial design. Additionally, the iterative second demographic design module 318 is configured to iteratively generate variations of a second demographic design based on second feedback votes received from the second virtual population model 314 as a predicted selection between competing second demographic designs, starting from the initial design.

In some aspects of the present disclosure, the user activity module 310 may be implemented and/or work in conjunction with the semi-automated design feedback loop server 370. In one implementation, a database (DB) 380 stores data related to designs of images/objects as well as previous designs of images/objects, which may be displayed as output through the user interface 302. In some aspects of the present disclosure, the semi-automated product design feedback loop system 300 may be implemented as a web browser plugin. In other aspects of the present disclosure, the semi-automated design feedback loop server 370 provides an offline application that scans content viewed through the user interface 302 as well as whiteboard presentations. In other aspects of the present disclosure, the semi-automated product design feedback loop system 300 may be implemented as a mobile application that augments the visual content design process by presenting iteratively modified designs based on predicted votes of different demographics.

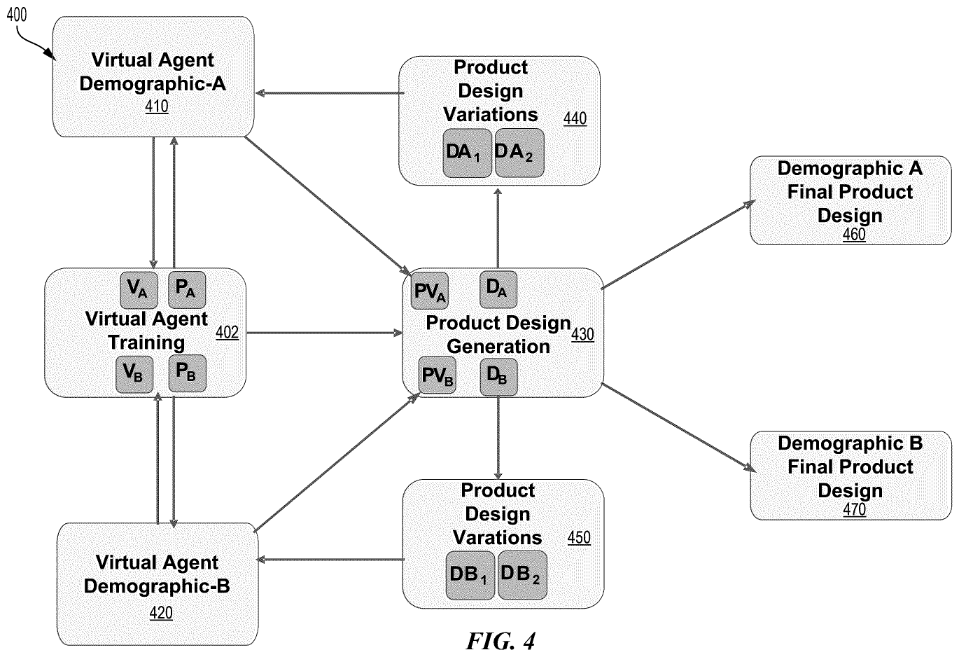

FIG. 4 is a block diagram illustrating a semi-automated product design feedback loop system 400, according to various aspects of the present disclosure. As shown in FIG. 4, the semi-automated product design feedback loop system 400 provides a framework for ideation across different demographic groups. In this implementation, the semi-automated product design feedback loop system 400 involves fine-tuning separate large language models (LLMs) on preferences of different demographic groups. These different demographic groups may be represented as virtual agents that are trained according to preference votes received from individuals of the different demographic groups. In some implementations of the machine learning (ML) models, the virtual agents are initializing a first seed dataset representing feedback from a first target population or a second seed dataset representing feedback from a second target population.

According to various aspects of the present disclosure, a virtual agent training module 402 trains a virtual population within a large language model (LLM) that represents a defined demographic (e.g., Japanese, American, etc.). This training includes defining preferences, styles, customs, and other aspects specific to the demographic relative to a product design. One way to achieve this training is by presenting variations of a product (e.g., P_{A} or P_{B}) and have individuals from the demographic vote (e.g., V_{A} or V_{B}) on which is a preferred variation of the product. In this example, the product variations (e.g., P_{A} or P_{B}) provided by the virtual agent training module 402 may be generated using a text-to-image model of the virtual agent training module 402.

In this implementation, the demographic votes V_{A}/V_{B} provide training data that can be used to fine-tune the LLMs for the different populations, which are shown as a virtual agent demographic-A 410 and a virtual agent demographic-B 420. For example, training a first virtual population in a first large language model (LLM) that represents a first defined demographic represented as the virtual agent demographic-A 410. Additionally, training a second virtual population in a second large language model (LLM) that represents a second defined demographic represented as the virtual agent demographic-B 420. Utilizing the virtual agent demographic-A 410 and the virtual agent demographic-B 420 to provide a feedback loop during the semi-automated product design avoids human bias in the product design. In particular, foreign and domestic product design integration is performed without involving human bias.

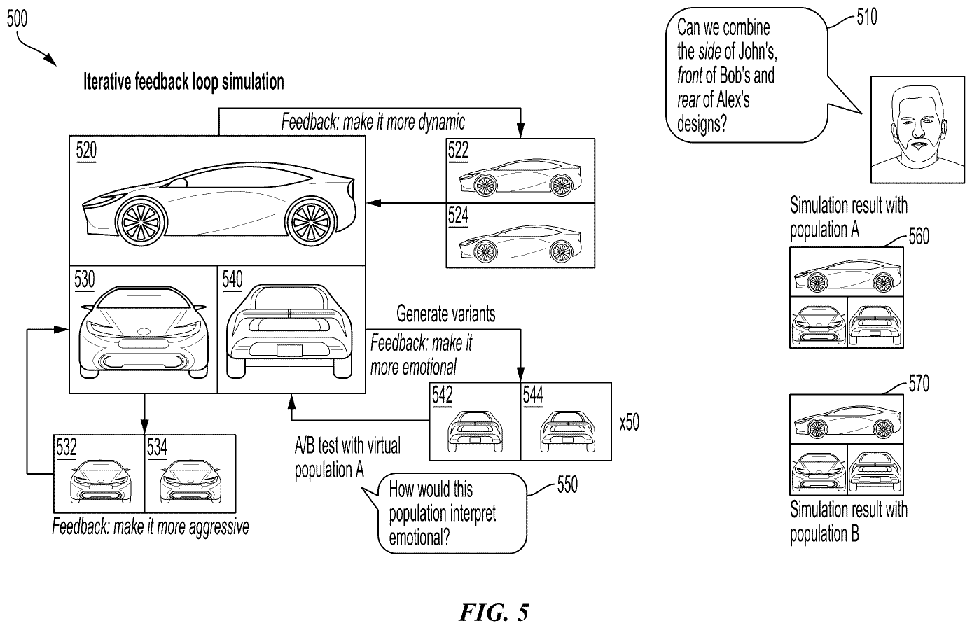

As further illustrated in FIG. 4, the semi-automated product design feedback loop system 400 contains a product design generation module 430. In this example, the product design generation module 430 iteratively modifies an initial design (e.g., D_{A}) based on a first feedback vote (e.g., PV_{A}) received from the virtual agent demographic-A 410 selecting between first product design variations 440 (e.g., DA₁ or DA₂) derived from the initial design D_{A}. Concurrently, the product design generation module 430 iteratively modifies an initial design (e.g., D_{B}) based on a second feedback vote (e.g., PV_{B}) received from the virtual agent demographic-B 420 selecting between second product design variations 450 (e.g., DB₁ or DB₂) derived from the initial design D_{B}. These concurrent loops may continue until a defined condition is met to generate a demographic-A final product design 460 and a demographic-B final product design 470, as further illustrated in FIG. 5.

FIG. 5 is a block diagram illustrating an iterative feedback loop simulation 500 for product design involving different populations, according to various aspects of the present disclosure. In this example, the following is provided as a query 510: “Can we combine the side of John's, front of Bob's and rear of Alex's designs?” Based on the query 510, a side of John's design 520, a front of Bob's design 530, and a back of Alex's design 540. Beginning with the side of John's design 520, the iterative feedback loop simulation 500 generates variations 522, 524 and has the virtual populations (e.g., population A/population B) vote on which is preferred until a defined condition is met (e.g., “Feedback: make it more dynamic”).

Similarly, based on the front of Bob's design 530, the iterative feedback loop simulation 500 generates variations 532, 534 and has the virtual populations (e.g., population A/population B) vote on which is preferred until a defined condition is met (e.g., “Feedback: make it more aggressive”). Additionally, based on the back of Alex's design 540, the iterative feedback loop simulation 500 generates variations 542, 544 and has the virtual populations (e.g., population A/population B) vote on which is preferred until a defined condition is met (e.g., Feedback: make it more emotional). In this example, the iterative feedback loop simulation 500 is repeated fifty times (50×), and includes an additional query 550: “How would this population interpret emotional?” This iteration loop notes an A/B test selection between the variations 542 and 544 with virtual population A.

In this implementation, the iterative feedback loop simulation 500 continues generating variations and has the virtual populations vote on which is preferred until a defined condition is met. The condition may be a defined goal, such as more dynamic, more aggressive, etc. Additionally, the iterative feedback loop simulation 500 can then iterate designs while acquiring feedback from the virtual population. The population can provide a simple vote or can include impressions of the iteration that is similar to the defined goal. The iterative feedback loop simulation 500 can perform these iterations on parallel designs with separate virtual populations, which provide separate population-based options that can then be reconciled or used as the basis of independent designs.

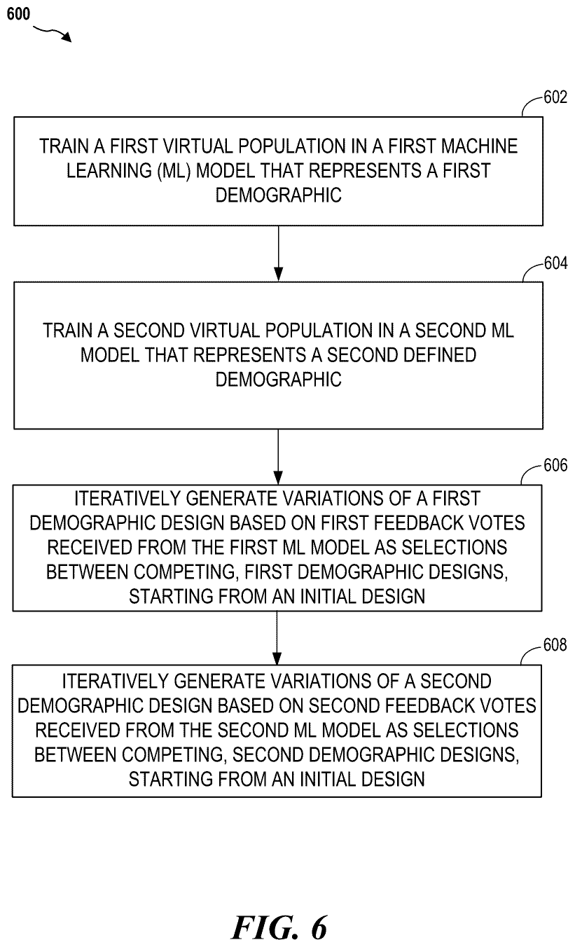

In this example, a simulation result illustrates a final version of a product design 560 with population A and a simulation result illustrates a final version of a product design 570 with population B are shown. According to various aspects of the present disclosure, the iterative feedback loop simulation 500 can perform this ideation and provide an output that shows the evolution of the design across iterations and populations. In this implementation, an architecture of the models to provide virtual agents representing population A and population B in combination with a multimodal generative mode operate in tandem to generate different design options focused on particular demographics, for example, as shown in FIG. 6.

FIG. 6 is a process flow diagram illustrating a method 600 for semi-automated product design, according to various aspects of the present disclosure. The method 600 begins at block 602, in which a first virtual population is trained in a first machine learning (ML) model that represents a first demographic. At block 604, a second virtual population is trained in a second ML model that represents a second defined demographic. For example, as shown in FIG. 4, the virtual agent training module 402 trains a virtual population within an LLM that represents a defined demographic (e.g., Japanese, American, etc.). This training includes defining preferences, styles, customs, and other aspects specific to the demographic relative to a product design. In this implementation, the demographic votes V_{A}/V_{B} provide training data that can be used to fine-tune the LLMs for the different populations, which are shown as a virtual agent demographic-A 410 and a virtual agent demographic-B 420. In this example, the first LLM represents a first defined demographic represented as the virtual agent demographic-A 410. Additionally, the second LLM represents a second defined demographic represented as the virtual agent demographic-B 420.

Utilizing the virtual agent demographic-A 410 and the virtual agent demographic-B 420 to provide a feedback loop during the semi-automated product design avoids human bias in the product design. In particular, foreign and domestic product design integration is performed without involving human bias.

At block 606, variations of a first demographic design are iteratively generated based on first feedback votes received from the first ML model as selections between competing, first demographic designs, starting from an initial design. At block 608, variations of a second demographic design are iteratively generated based on second feedback votes received from the second ML model as a selection between competing, second demographic designs, starting from the initial design.

For example, as shown in FIG. 4, the product design generation module 430 iteratively modifies an initial design (e.g., D_{A}) based on a first feedback vote (e.g., PV_{A}) received from the virtual agent demographic-A 410 selecting between first product design variations 440 (e.g., DA₁ or DA₂) derived from the initial design D_{A}. Concurrently, the product design generation module 430 iteratively modifies an initial design (e.g., D_{B}) based on a second feedback vote (e.g., PV_{B}) received from the virtual agent demographic-B 420 selecting between second product design variations 450 (e.g., DB₁ or DB₂) derived from the initial design D_{B}. These concurrent loops may continue until a defined condition is met to generate a demographic-A final product design 460 and a demographic-B final product design 470

The various operations of methods described above may be performed by any suitable means capable of performing the corresponding functions. The means may include various hardware and/or software component(s) and/or module(s), including, but not limited to, a circuit, an application-specific integrated circuit (ASIC), or processor. Where there are operations illustrated in the figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Additionally, “determining” may include receiving (e.g., receiving information), accessing (e.g., accessing data in a memory), and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a processor configured according to the present disclosure, a digital signal processor (DSP), an ASIC, a field-programmable gate array signal (FPGA) or other programmable logic device (PLD), discrete gate or transistor logic, discrete hardware components, or any combination thereof designed to perform the functions described herein. The processor may be a microprocessor, but, in the alternative, the processor may be any commercially available processor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read-only memory (ROM), flash memory, erasable programmable read-only memory (EPROM), electrically erasable programmable read-only memory (EEPROM), registers, a hard disk, a removable disk, a CD-ROM, and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may connect a network adapter, among other things, to the processing system via the bus. The network adapter may implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and processing, including the execution of software stored on the machine-readable media. Examples of processors that may be specially configured according to the present disclosure include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, RAM, flash memory, ROM, programmable read-only memory (PROM), EPROM, EEPROM, registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in several ways, such as certain components being configured as part of a distributed computing system.

The processing system may be configured with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described herein. As another alternative, the processing system may be implemented with an ASIC with the processor, the bus interface, the user interface, supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functions described throughout this present disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a special purpose register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a non-transitory computer-readable medium. Computer-readable media include both computer storage media and communication media, including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects, computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a CD or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A method for a semi-automated product design, the method comprising:
training a first virtual population in a first machine learning (ML) model that represents a first demographic;
training a second virtual population in a second ML model that represents a second defined demographic;
iteratively generating variations of a first demographic design based on first feedback votes received from the first ML model as selections between competing, first demographic designs, starting from an initial design; and
iteratively generating variations of a second demographic design based on second feedback votes received from the second ML model as a selection between competing, second demographic designs, starting from the initial design.

2. The method of claim 1, in which training the first virtual population comprises:
presenting variations of a product to individuals of the first demographic; and
accumulating training data for the first virtual population according to votes from the individuals of the first demographic directed to a preferred variation of the product.

3. The method of claim 1, in which training the second virtual population comprises:
presenting variations of a product to individuals of the second demographic; and
accumulating training data for the second virtual population according to votes from the individuals of the second demographic directed to a preferred variation of the product.

4. The method of claim 1, in which iteratively generating variations of the first demographic design comprises:
periodically displaying one or more of the generated variations of the first demographic design to a user of the first demographic;
receiving, from the user, feedback including rank ordering and/or selection of preferred design variants from the one or more of the generated variations of the first demographic design; and
providing the received feedback to the first ML model.

5. The method of claim 1, in which iteratively generating variations of the second demographic design comprises:
periodically displaying one or more of the generated variations of the second demographic design to a user of the first demographic;
receiving, from the user, feedback including rank ordering and/or selection of preferred design variants from the one or more of the generated variations of the second demographic design; and
providing the received feedback to the second ML model.

6. The method of claim 1, further comprising:
displaying, through a user interface, a final version of the first demographic design; and
concurrently displaying, through the user interface, a final version of the second demographic design.

7. The method of claim 6, further comprising reconciling the final version of the first demographic design and the final version of the second demographic design.

8. The method of claim 7, further comprising:
initializing the first ML model with a first seed dataset; and
initializing the second ML model with a second seed dataset.

9. The method of claim 1, in which iteratively generating variations of the first demographic design is performed until a predetermined condition is satisfied.

10. The method of claim 1, in which iteratively generating variations of the second demographic design is performed until a predetermined condition is satisfied.

11. A non-transitory computer-readable medium having program code recorded thereon for a semi-automated product design, the program code being executed by a processor and comprising:
program code to train a first virtual population in a first machine learning (ML) model that represents a first demographic;
program code to train a second virtual population in a second ML model that represents a second defined demographic;
program code to iteratively generate variations of a first demographic design based on first feedback votes received from the first ML model as selections between competing, first demographic designs, starting from an initial design; and
program code to iteratively generate variations of a second demographic design based on second feedback votes received from the second ML model as a selection between competing, second demographic designs, starting from the initial design.

12. The non-transitory computer-readable medium of claim 11, in which the program code to train the first virtual population comprises:
program code to present variations of a product to individuals of the first demographic; and
program code to accumulate training data for the first virtual population according to votes from the individuals of the first demographic directed to a preferred variation of the product.

13. The non-transitory computer-readable medium of claim 11, in which the program code to train the second virtual population comprises:
program code to present variations of a product to individuals of the second demographic; and
program code to accumulate training data for the second virtual population according to votes from the individuals of the second demographic directed to a preferred variation of the product.

14. The non-transitory computer-readable medium of claim 11, in which the program code to iteratively generate variations of the first demographic design comprises:
program code to periodically display one or more of the generated variations of the first demographic design to a user of the first demographic;
program code to receive, from the user, feedback including rank ordering and/or selection of preferred design variants from the one or more of the generated variations of the first demographic design; and
program code to provide the received feedback to the first ML model.

15. The non-transitory computer-readable medium of claim 11, in which the program code to iteratively generate variations of the second demographic design comprises:
program code to periodically display one or more of the generated variations of the second demographic design to a user of the first demographic;
program code to receive, from the user, feedback including rank ordering and/or selection of preferred design variants from the one or more of the generated variations of the second demographic design; and
program code to provide the received feedback to the second ML model.

16. The non-transitory computer-readable medium of claim 11, further comprising:
program code to display, through a user interface, a final version of the first demographic design;
program code to concurrently display, through the user interface, a final version of the second demographic design; and
program code to reconcile the final version of the first demographic design and the final version of the second demographic design.

17. The non-transitory computer-readable medium of claim 11, further comprising:
program code to initialize the first ML model with a first seed dataset; and
program code to initialize the second ML model with a second seed dataset.

18. A system for a semi-automated product design, the system comprising:
a first virtual population model trained according to a first virtual population using a first machine learning (ML) model that represents a first demographic;
a first virtual population model to trained according to a second virtual population in using a second ML model that represents a second defined demographic;
an iterative first demographic design module to iteratively generate variations of a first demographic design based on first feedback votes received from the first ML model as selections between competing, first demographic designs, starting from an initial design; and
an iterative first demographic design module to iteratively generate variations of a second demographic design based on second feedback votes received from the second ML model as a selection between competing, second demographic designs, starting from the initial design.

19. The system of claim 18, in which the iterative first demographic design module is further to periodically display one or more of the generated variations of the first demographic design to a user of the first demographic, to receive, from the user, feedback including rank ordering and/or selection of preferred design variants from the one or more of the generated variations of the first demographic design, and program code to provide the received feedback to the first ML model.

20. The system of claim 18, in which the iterative first demographic design module is further to periodically display one or more of the generated variations of the second demographic design to a user of the first demographic, to receive, from the user, feedback including rank ordering and/or selection of preferred design variants from the one or more of the generated variations of the second demographic design, and program code to provide the received feedback to the second ML model.
